(19) United States
(12) Patent Application Publication
(10) Pub. No.: US 2011/0012187 A1
(43) Pub. Date: Jan. 20, 2011

(54) NON-VOLATILE SEMICONDUCTOR MEMORY DEVICE AND METHOD OF MANUFACTURING THE SAME

(75) Inventor: Hiroyuki ISHII, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/837,923

(22) Filed: Jul. 16, 2010

(30) Foreign Application Priority Data
Jul. 17, 2009 (JP) 2009-168753

(51) Int. Cl. H01L 29/788; H01L 29/792; H01L 21/336

(52) U.S. Cl. 257/321; 257/324; 438/587; 257/E29.304; 257/E29.309; 257/E21.422

(57) ABSTRACT

A semiconductor memory device includes: a semiconductor substrate; an element isolation insulating film dividing the semiconductor substrate into a plurality of element regions; tunnel insulating films formed respectively on the plurality of element regions; floating gate electrodes formed respectively on the tunnel insulating films; a first control-gate electrode formed, on the floating gate electrodes and between each two floating gate electrodes adjacent to each other in a channel-width direction, with a laminated insulating film interposed therebetween; assist insulating films formed on side surface facing in the channel-width direction of the plurality of element regions; and a second control-gate electrode formed between the plurality of element regions with the assist insulating films interposed therebetween.

### CROSS-REFERENCE TO RELATED APPLICATIONS

This application is based upon and claims the benefit of priority from the prior Japanese Patent Application No. 2009-168753, filed Jul. 7, 2009, the entire contents of which are incorporated herein by reference.

### BACKGROUND OF THE INVENTION

1. Field of the Invention

The present invention relates to a non-volatile semiconductor memory device and a method of manufacturing a non-volatile semiconductor memory device. Specifically, the present invention relates to a non-volatile semiconductor memory device including a floating gate electrode and a control-gate electrode, and to a method of manufacturing such a non-volatile semiconductor memory device.

2. Description of the Related Art

In recent years, memory-cell transistors have been shrunk more and more. Along with the trend, the pitch at which memory-cell transistors are arranged has become narrower and narrower. Consequently, memory-cell transistors that are adjacent to each other are more likely to interfere with each other (hereafter, the phenomenon will be referred to as “inter-cell interference”).

Inter-cell interference is a phenomenon that occurs when data are written into floating-gate-type memory-cell transistors. Specifically, when writing data into a first one of the memory-cell transistors is followed by writing data into a second memory-cell transistor thereof that is adjacent to the first one, the threshold voltage of the first memory-cell transistor appears to rise. In general, inter-cell interference, if occurs, may cause an error in reading data from memory-cell transistors (hereafter, the kind of error will be referred to as “read-out error”).

A known non-volatile semiconductor memory device prevents the inter-cell interference from occurring by providing a shield electrode between every adjacent memory-cell transistors (see, Japanese Patent Application Publication No. 2003-188287).

In the non-volatile semiconductor memory device of JP-A 2003-188287, each of the shield electrodes is formed between every two adjacent memory-cell transistors arranged in the so-called “word-line direction,” but no such shield electrodes are formed in the bit-line direction. Accordingly, the shield electrodes are unsatisfactory as means for solving the problem of inter-cell interference.

That current flows only in the channel region under the gate electrode. It makes the transconductance so low and, the current flows extremely low in the reading data. Consequently, it becomes difficult to determine normally the data-storing state of each memory-cell transistor. It is easy to occur read-out errors in the memory-cell transistor, especially that of multi-value kind.

### BRIEF SUMMARY OF THE INVENTION

A semiconductor memory device according to an aspect of the present invention includes: a semiconductor substrate; an element isolation insulating film dividing the semiconductor substrate into a plurality of element regions; tunnel insulating films formed respectively on the plurality of element regions; floating gate electrodes formed respectively on the tunnel insulating films; a first control-gate electrode formed, on the floating gate electrodes and between each two floating gate electrodes adjacent to each other in a channel-width direction, with a laminated insulating film interposed therebetween; assist insulating films formed on side surface facing in the channel-width direction of the plurality of element regions; and a second control-gate electrode formed between the plurality of element regions with the assist insulating films interposed therebetween.

A method of manufacturing semiconductor memory device according to an aspect of the present invention includes: forming a stopper insulating film on a semiconductor substrate; etching the semiconductor substrate and the stopper insulation film, and thereby forming element-isolation grooves to divide the semiconductor substrate into a plurality of element regions; forming element-isolation insulating films by burying insulating films into the element-isolation grooves; etching back the element-isolation insulating films to a predetermined depth so that a side surface of the plurality of element regions are exposed; forming assist insulating films on the side surface of the plurality of element regions exposed from the element-isolation insulating films, on the stopper insulating film, and on the element-isolation insulating films; forming second control-gate electrodes between the plurality of element regions with the assist insulating films interposed therebetween; forming tunnel insulating films on the plurality of element regions respectively; forming floating gate electrodes on the tunnel insulating films respectively; forming a laminated insulating film on the floating gate electrodes and on the second control-gate electrodes; and forming a first control-gate electrode on the laminated insulating film.

### BRIEF DESCRIPTION OF THE SEVERAL VIEWS OF THE DRAWINGS

FIG. 1A is a plan view illustrating the structure of a non-volatile semiconductor memory device according to an embodiment of the present invention.

FIG. 1B is a sectional view taken along the line A-A of FIG. 1A.

FIG. 2 is a sectional view illustrating the structure of a non-volatile semiconductor memory device according to a modified example of the embodiment of the present invention.

FIG. 3A is a sectional view illustrating a process included in a method of manufacturing a non-volatile semiconductor memory device according to an embodiment of the present invention. Specifically, the sectional view illustrates a process of forming a memory-cell-transistor region.

FIG. 3B is sectional view illustrating a process included in the method of manufacturing a non-volatile semiconductor memory device according to the embodiment of the present invention. Specifically, the sectional view illustrates a process of forming a peripheral-circuit-transistor region.

FIG. 4A is a sectional view illustrating a process included in the method of manufacturing a non-volatile semiconductor memory device according to the embodiment of the present invention. Specifically, the sectional view illustrates a process following the process illustrated in FIG. 3A.

FIG. 4B is a sectional view illustrating a process included in the method of manufacturing a non-volatile semiconductor memory device according to the embodiment of the present invention. Specifically, the sectional view illustrates a process following the process illustrated in FIG. 3B.

FIG. 5A is a sectional view illustrating a process included in the method of manufacturing a non-volatile semiconductor memory device according to the embodiment of the present invention. Specifically, the sectional view illustrates a process following the process illustrated in FIG. 4A.

FIG. 5B is a sectional view illustrating a process included in the method of manufacturing a non-volatile semiconductor memory device according to the embodiment of the present invention. Specifically, the sectional view illustrates a process following the process illustrated in FIG. 4B.

FIG. 6A is a sectional view illustrating a process included in the method of manufacturing a non-volatile semiconductor memory device according to the embodiment of the present invention. Specifically, the sectional view illustrates a process following the process illustrated in FIG. 5A.

FIG. 6B is a sectional view illustrating a process included in the method of manufacturing a non-volatile semiconductor memory device according to the embodiment of the present invention. Specifically, the sectional view illustrates a process following the process illustrated in FIG. 5B.

FIG. 7A is a sectional view illustrating a process included in the method of manufacturing a non-volatile semiconductor memory device according to the embodiment of the present invention. Specifically, the sectional view illustrates a process following the process illustrated in FIG. 6A.

FIG. 7B is a sectional view illustrating a process included in the method of manufacturing a non-volatile semiconductor memory device according to the embodiment of the present invention. Specifically, the sectional view illustrates a process following the process illustrated in FIG. 6B.

FIG. 8A is a sectional view illustrating a process included in the method of manufacturing a non-volatile semiconductor memory device according to the embodiment of the present invention. Specifically, the sectional view illustrates a process following the process illustrated in FIG. 7A.

FIG. 8B is a sectional view illustrating a process included in the method of manufacturing a non-volatile semiconductor memory device according to the embodiment of the present invention. Specifically, the sectional view illustrates a process following the process illustrated in FIG. 7B.

FIG. 9A is a sectional view illustrating a process included in the method of manufacturing a non-volatile semiconductor memory device according to the embodiment of the present invention. Specifically, the sectional view illustrates a process following the process illustrated in FIG. 8A.

FIG. 9B is a sectional view illustrating a process included in the method of manufacturing a non-volatile semiconductor memory device according to the embodiment of the present invention. Specifically, the sectional view illustrates a process following the process illustrated in FIG. 8B.

FIG. 10A is a sectional view illustrating a process included in the method of manufacturing a non-volatile semiconductor memory device according to the embodiment of the present invention. Specifically, the sectional view illustrates a process following the process illustrated in FIG. 9A.

FIG. 10B is a sectional view illustrating a process included in the method of manufacturing a non-volatile semiconductor memory device according to the embodiment of the present invention. Specifically, the sectional view illustrates a process following the process illustrated in FIG. 9B.

FIG. 11A is a sectional view illustrating a process included in the method of manufacturing a non-volatile semiconductor memory device according to the embodiment of the present invention. Specifically, the sectional view illustrates a process following the process illustrated in FIG. 10A.

FIG. 11B is a sectional view illustrating a process included in the method of manufacturing a non-volatile semiconductor memory device according to the embodiment of the present invention. Specifically, the sectional view illustrates a process following the process illustrated in FIG. 10B.

FIG. 12A is a sectional view illustrating a process included in the method of manufacturing a non-volatile semiconductor memory device according to the embodiment of the present invention. Specifically, the sectional view illustrates a process following the process illustrated in FIG. 11A.

FIG. 12B is a sectional view illustrating a process included in the method of manufacturing a non-volatile semiconductor memory device according to the embodiment of the present invention. Specifically, the sectional view illustrates a process following the process illustrated in FIG. 11B.

FIG. 13A is a sectional view illustrating a process included in the method of manufacturing a non-volatile semiconductor memory device according to the embodiment of the present invention. Specifically, the sectional view illustrates a process following the process illustrated in FIG. 12A.

FIG. 13B is a sectional view illustrating a process included in the method of manufacturing a non-volatile semiconductor memory device according to the embodiment of the present invention. Specifically, the sectional view illustrates a process following the process illustrated in FIG. 12B.

FIG. 14A is a sectional view illustrating a process included in the method of manufacturing a non-volatile semiconductor memory device according to the embodiment of the present invention. Specifically, the sectional view illustrates a process following the process illustrated in FIG. 13A.

FIG. 14B is a sectional view illustrating a process included in the method of manufacturing a non-volatile semiconductor memory device according to the embodiment of the present invention. Specifically, the sectional view illustrates a process following the process illustrated in FIG. 13B.

FIG. 15A is a sectional view illustrating a process included in the method of manufacturing a non-volatile semiconductor memory device according to the embodiment of the present invention. Specifically, the sectional view illustrates a process following the process illustrated in FIG. 14A.

FIG. 15B is a sectional view illustrating a process included in the method of manufacturing a non-volatile semiconductor memory device according to the embodiment of the present invention. Specifically, the sectional view illustrates a process following the process illustrated in FIG. 14B.

FIG. 16A is an enlarged view illustrating the region demarcated by the dashed line B of FIG. 1B.

FIG. 16B is an enlarged view illustrating the region demarcated by the dashed line B of FIG. 1B.

FIG. 17 is a graph to describe a comparative example of Operational Example 1 of the embodiment of the present invention.

### DETAILED DESCRIPTION OF THE INVENTION

Some embodiments of the present invention will be described in detail below by referring to the drawings.

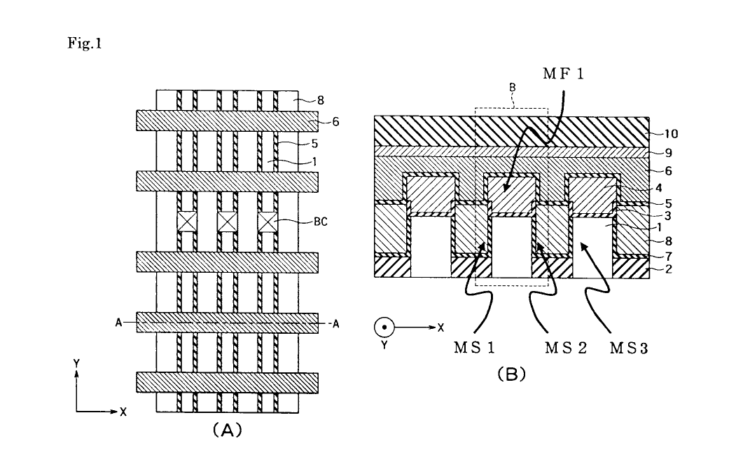

Firstly, description will be given of the structure of a non-volatile semiconductor memory device according to an embodiment of the present invention. FIG. 1 illustrates the structure of a non-volatile semiconductor memory device according to an embodiment of the present invention. FIG. 1A is a plan view illustrating the structure of a memory-cell array of the non-volatile semiconductor memory device according to the embodiment of the present invention. FIG. 1B is a view illustrating a section taken along the dashed line A of FIG. 1A.

The non-volatile semiconductor memory device of FIG. 1A according to the embodiment of the present invention includes bit-line contacts BC connected to bit lines (not illustrated) in the memory-cell array. The non-volatile semiconductor memory device also includes plural first control-gate electrodes 6 and plural second control-gate electrodes 8. The first control-gate electrodes 6 are arranged, at certain intervals, in the direction in which the bit lines extend (in the Y-direction in FIG. 1A). The second control-gate electrodes 8 are arranged in the direction in which the control gate extends (in the X-direction in FIG. 1A). Each of the second control-gate electrodes 8 is separated from the adjacent one with a laminated insulating film 5 and an element region. Hereafter, the second control-gate electrodes 8 will be referred also to as “sidewall gate electrodes.” In addition, the X-direction will be referred to as either the “bit-line direction” or the “channel-width direction.” The Y-direction will be referred to as either the word-line direction” or the “channel-length direction.”

As shown in FIG. 1B, the non-volatile semiconductor memory device according to the embodiment of the present invention illustrated in the section taken along the line A-A of FIG. 1A includes a semiconductor substrate 1, element-isolation insulating films 2, tunnel insulating films 3, floating gate electrodes 4, the laminated insulating films 5, the first control-gate electrodes 6, assist insulating films 7, the second control-gate electrodes 8, a metal layer 9, and a tetra-ethyl-ortho-silicate (TEOS) film 10. The semiconductor substrate 1 is, for instance, a silicon substrate. The element-isolation insulating films 2 are, for instance, high-density plasma (HDP) films, and divide the semiconductor substrate 1 into plural element regions arranged in the channel-width direction (in the X-direction in FIG. 1B). The tunnel insulating films 3 are formed, respectively, on the element regions of the semiconductor substrate 1. The floating gate electrodes 4 are made, for instance, of poly silicon. The floating gate electrodes 4 are formed, respectively, on the tunnel insulating films 3, and are arranged, at certain intervals, in the channel-width direction. The laminated insulating films 5 are, for instance, oxide-nitride-oxide (ONO) films. The laminated insulating films 5 are formed continuously in the channel-width direction so as to cover the floating gate electrodes 4. The first control-gate electrodes 6 are formed, on the floating gate electrodes 4 and between each two floating gate electrodes 4 adjacent to each other in the channel-width direction, with the laminated insulating film 5 interposed therebetween. The assist insulating films 7 are, for instance, ONO films. The assist insulating films 7 are formed on side surface of the element regions facing the channel-width direction of the semiconductor substrate 1. The second control-gate electrodes 8 are electrodes made, for instance, of poly silicon. The second control-gate electrodes 8 are formed between the plural element regions with the assist insulating films 7 interposed therebetween. The metal layer 9 is, for instance, a tungsten-silicon layer. The metal layer 9 is formed on the laminated insulating films 5. The TEOS film 10 is formed on the metal layer 9. Each of the assist insulating films 7 includes a nitride film formed as the central layer and serving as a nitride-film trap layer. The top surface of each second control-gate electrode 8 is located at a higher position than the top surfaces of the channel regions formed on the surface of the semiconductor substrate 1.

In the non-volatile semiconductor memory device according to the embodiment of the present invention, the channel regions are formed not only below the floating gate electrodes 4 but also on a side portion of the element regions facing to the second control-gate electrode 81. The channel regions formed on the side portion of the element regions function as non-volatile memory-cell transistors by trapping electrons in the nitride films. To put it differently, non-volatile memory-cell transistors of SONOS (silicon-oxide-nitride-oxide-silicon) type are formed on the side portion of the element regions.

As FIG. 2 shows, a non-volatile semiconductor memory device according to a modified example of the embodiment of the present invention may include SONOS-type non-volatile memory-cell transistors. The SONOS-type non-volatile memory-cell transistors function as non-volatile memory-cell transistors by trapping electrons in the nitride films, in place of the floating gate electrodes 4 shown in FIG. 1B. In this case, the laminated insulating films 5 shown in FIG. 1B are replaced with laminated insulating films 5′ that include a set of an ONO film, a silicon-nitride film, and a ferroelectric film (e.g., alumina film), or a set of a silicon-oxide film, a silicon-nitride film, and a ferroelectric film.

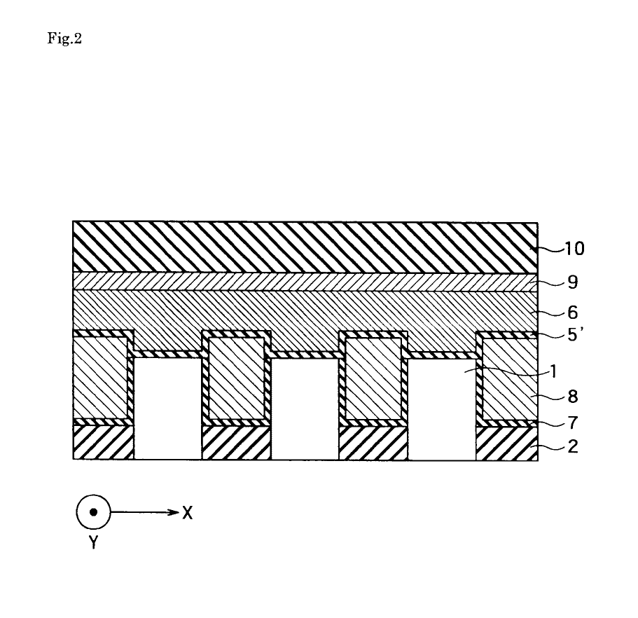

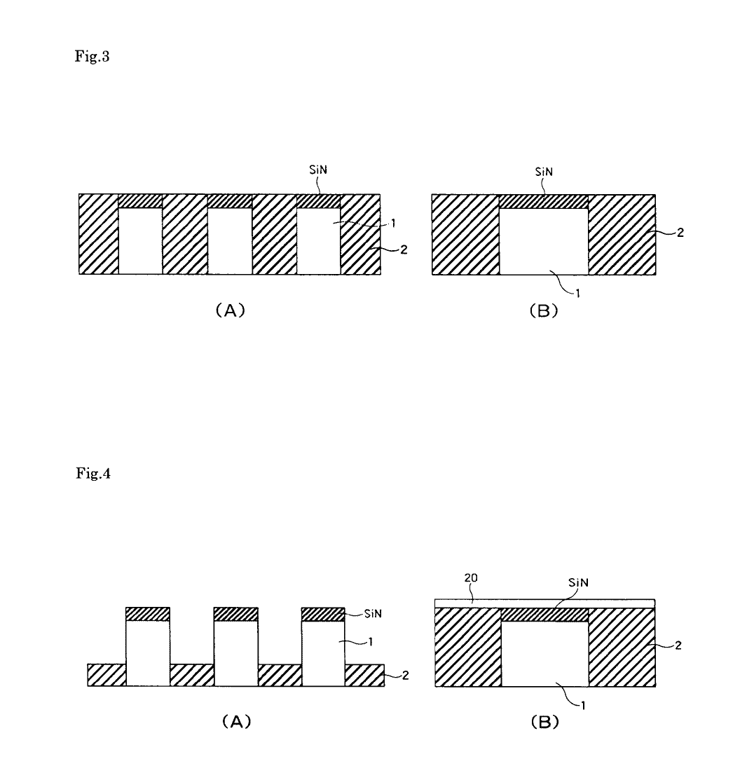

Next, description will be given of a method of manufacturing a non-volatile semiconductor memory device according to an embodiment of the present invention. FIGS. 3A and 3B to 15A and 15B are sectional views illustrating processes included in the method of manufacturing a non-volatile semiconductor memory device according to the embodiment of the present invention. Each of FIGS. 3A to 15A shows a section of the memory-cell-transistor region whereas each of FIGS. 3B to 15B shows a section of peripheral-transistor region.

A nitride film SiN serving as a stopper insulating film is deposited on the semiconductor substrate 1 both in the memory-cell-transistor region and in the peripheral-circuit-transistor region as shown in FIGS. 3A and 3B, respectively. The nitride film SiN has a thickness ranging from 300 nm to 350 nm. Subsequently, the element-isolation insulating films 2 are formed, in a lithography process, so as to divide the semiconductor substrate 1 into plural element regions. Each of the element regions has a depth ranging from 100 nm to 500 nm measured from the surface of the semiconductor substrate 1. Subsequently, to recover from the damage in the substrate done in the lithography process, a post-oxidation film (not illustrated) is formed by a post-oxidation process. After that, such films as silicon-oxide films or insulating-coat films are buried into the element-isolation regions. Then, in a process of chemical mechanical polishing (hereafter referred to as the “CMP” process) using the nitride film SiN as a stopper, the element-isolation insulating films 2 is flattened. Consequently, element regions are formed in the semiconductor substrate 1. Note that in the embodiment of the present invention, the element-isolation insulating films 2 of the memory-cell-transistor region shown in FIG. 3A may have a depth and a width that are different from their respective counterparts in the peripheral-circuit-transistor region shown in FIG. 3B.

Then, in the memory-cell-transistor region shown in FIG. 4A, the element-isolation insulating films 2 are etched back by an etching process with an etching selectivity with respect to the nitride film SiN. As a result, the side surface of the channel regions of the semiconductor substrate 1 is exposed. On the other hand, the etching back is not necessary in the peripheral-circuit-transistor region shown in FIG. 4B. Accordingly, resist 20 is formed to cover entirely the peripheral-circuit-transistor region.

The resist 20 is removed from the peripheral-circuit-transistor region as shown in FIG. 5B. Subsequently, the assist insulating films 7 are deposited in both the memory-cell-transistor region and the peripheral-circuit-transistor region as shown in FIGS. 5A and 5B. The assist insulating films 7 serving as sidewall memory portions are deposited to the side surface of the element regions. The assist insulating films 7 are formed continuously on the side surface of the channel regions, the nitride films SiN, and the element-isolation insulating films 2. The assist insulating films 7 are, for instance, ONO films. In each of the assist insulating films 7, the oxide film of the uppermost layer has a thickness ranging from 15 nm to 30 nm. The nitride film of the central layer has a thickness ranging from 4 nm to 10 nm. The oxide film of the lowermost layer has a thickness ranging from 2 nm to 4 nm.

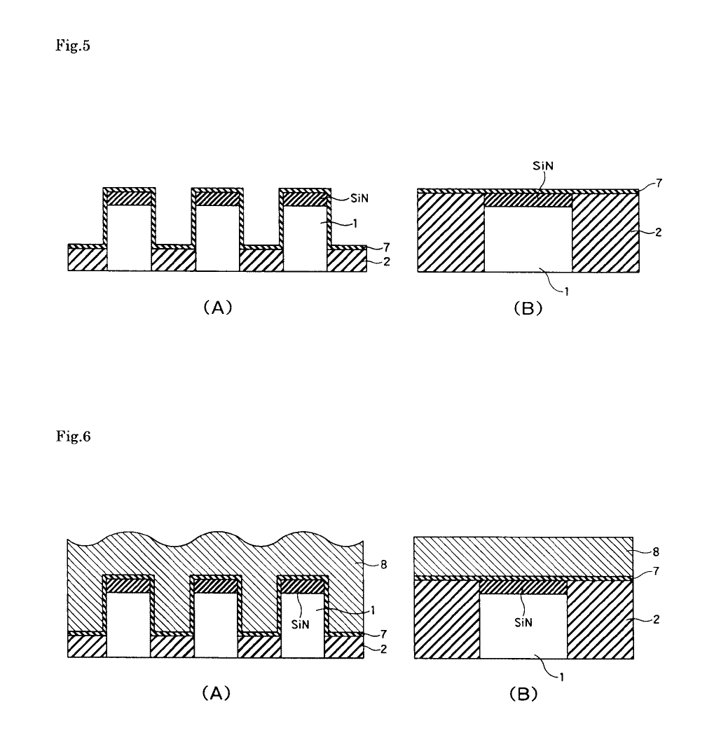

Then, poly silicon is deposited both in the memory-cell-transistor region and in the peripheral-circuit-transistor region as shown in FIGS. 6A and 6B, respectively. The poly silicon is to become the second control-gate electrodes 8, which serve as sidewall gate electrodes and as the shield against the inter-cell interference. The second control-gate electrodes 8 are formed between element regions with the assist insulating films 7 interposed therebetween.

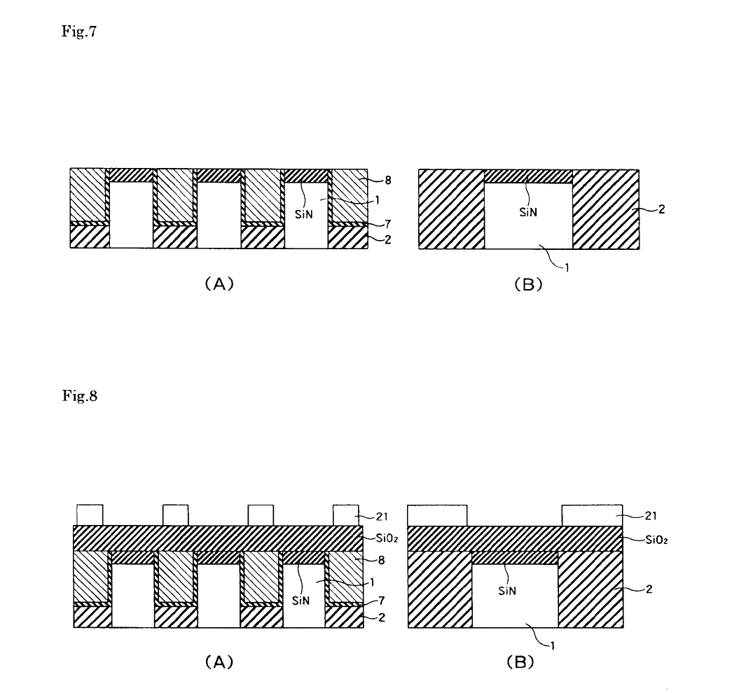

Then, by a CMP process using the nitride films SiN as stoppers, the poly silicon to be the second control-gate electrodes 8 is flattened both in the memory-cell-transistor region and in the peripheral-circuit-transistor region as shown in FIGS. 7A and 7B. Note that, in the peripheral-circuit-transistor region, the top surface of each nitride film SiN and the top surfaces of the element-isolation insulating films 2 are positioned at the same level as FIG. 7B shows. When the poly silicon to be the second control-gate electrodes 8 is flattened in the CMP process, both the assist insulating films 7 and the poly silicon to be the second control-gate electrodes 8 are removed in the peripheral-circuit-transistor region. Note that the nitride film included in each of the assist insulating films 7 is thin, specifically, has a thickness ranging from 4 nm to 10 nm. Accordingly, not only the second control-gate electrodes 8 but also the assist insulating films 7 formed on the nitride films SiN and on the element-isolation insulating films 2 are removed in the process of flattening the poly silicon.

An oxide film SiO₂ is deposited both in the memory-cell-transistor region and in the peripheral-circuit-transistor region as shown in FIGS. 8A and 8B. The oxide film SiO₂ thus deposited is to be used as a stopper in a CMP process to form floating gates. Subsequently, a photo resist 21 is formed. Then, opening portions are formed in the photo resist 21 by a lithography process. Each of a width of the opening portions is wider than that of element region so as to have a certain lithography margin.

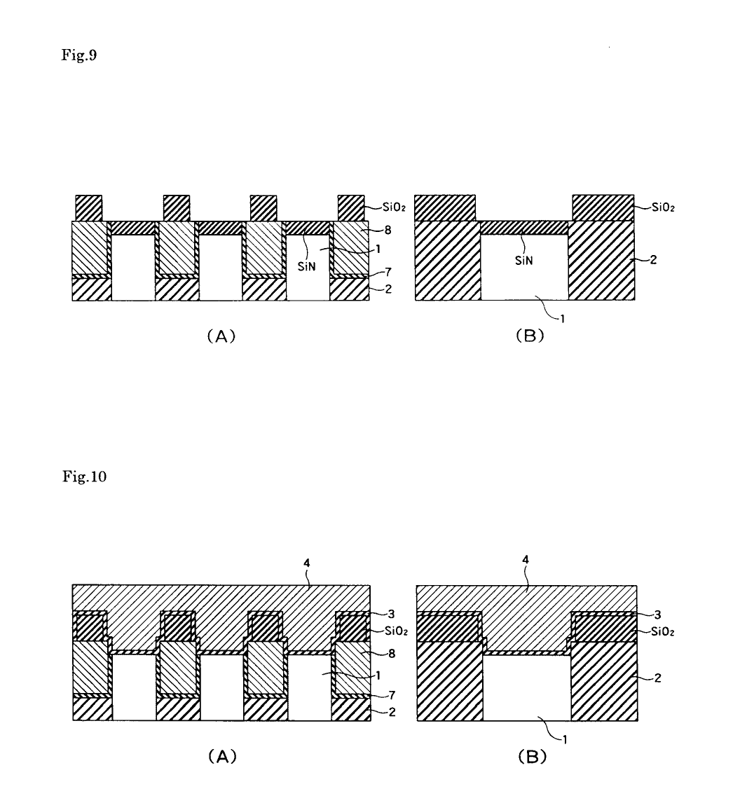

The oxide film SiO₂ is removed, by an etching process, both from the memory-cell-transistor region and from the peripheral-circuit-transistor region as shown in FIGS. 9A and 9B, respectively. As a result, the nitride films SiN are exposed.

The nitride films SiN are removed from the memory-cell-transistor region and from the peripheral-circuit-transistor region as shown in FIGS. 10A and 10B, respectively. Here, some portions of the assist insulating films 7 may also be removed from the memory-cell-transistor region. The assist insulating films 7 exposed from the semiconductor substrate 1 (i.e., the assist insulating films 7 contacting to the nitride film SiN) may be removed. Then, a silicon-oxide film that is to be the tunnel insulating films 3 is deposited. After that, poly silicon that is to be the floating gate electrodes 4 is deposited. The tunnel insulating films 3 are formed on the element regions of the semiconductor substrate 1 whereas the poly silicon to be the floating gate electrodes 4 are formed on the tunnel insulating films 3. Note that, in some embodiments of the present invention, the tunnel insulating films 3 may be formed also on the upper portions of the side surface of the second control-gate electrodes 8.

A resist 22 is formed to cover entirely the surface of the memory-cell-transistor region as shown in FIG. 11A. Note that the gate insulating film used for the peripheral-circuit transistors such as one shown in the FIG. 11B has a thickness that is different from the thickness of the tunnel insulating film 3 for the memory-cell transistors. So, unillustrated resist is formed to cover the memory-cell-transistor region, and then both the poly silicon that is to be the floating gate electrodes 4 and the tunnel insulating films 3 are removed. After the removal of the resist, poly silicon that is to be gate insulating films 3′ and poly silicon that is to be lower-layer gate electrodes 4′ are deposited in the peripheral-circuit transistors.

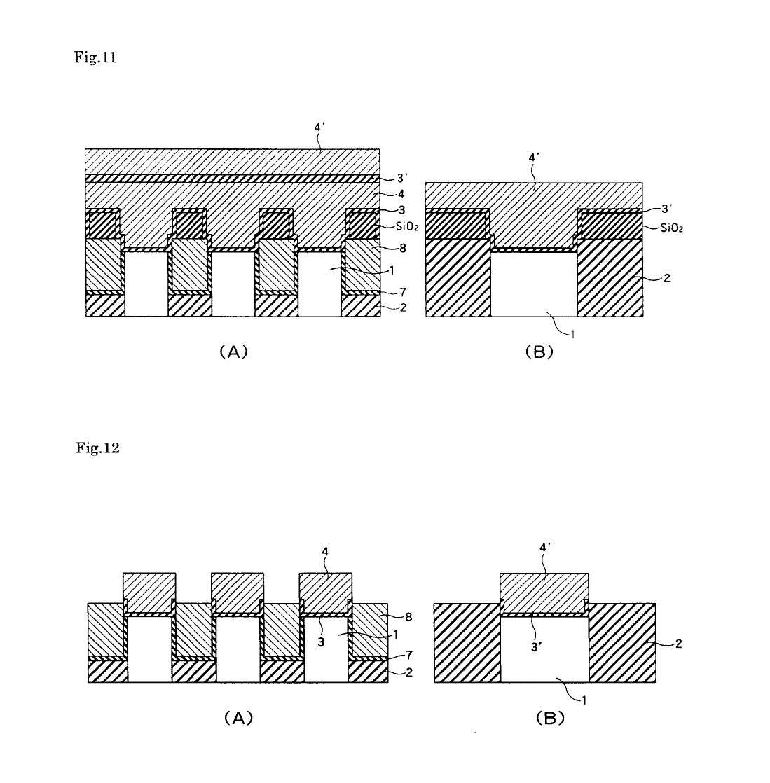

Both the poly silicon that is to be the floating gate electrodes 4 in the memory-cell-transistor region and the poly silicon that is to be the lower-layer gate electrodes 4′ in the peripheral-circuit-transistor region are flattened, by a CMP process using the oxide films SiO₂ as stoppers, as shown in FIGS. 12A and 12B, respectively. Then, the oxide films SiO₂ are removed by an etching process.

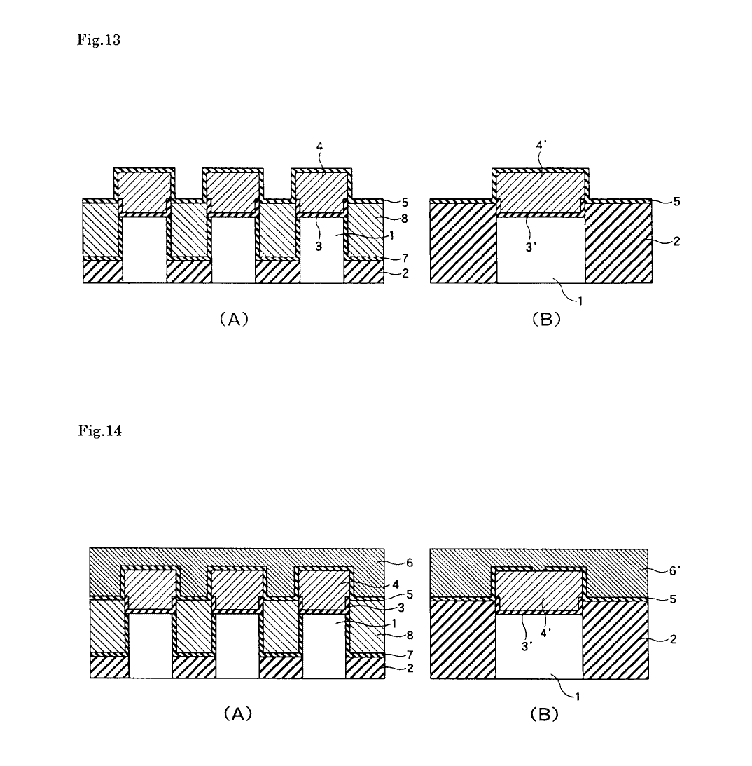

The laminated insulating film 5 is deposited both in the memory-cell-transistor region and in the peripheral-circuit-transistor region as shown in FIGS. 13A and 13B. The laminated insulating film 5 to insulate the first control-gate electrodes 6 (which will be described in detail later) and the floating gate electrodes 4 from each other is formed in the memory-cell-transistor region. In addition, the laminated insulating film 5 insulates upper-layer gate electrodes 6′ (which will be described in detail later) and the lower-layer gate electrodes 4′ from each other in the peripheral-circuit-transistor region. In the memory-cell-transistor region, the laminated insulating film 5 is formed continuously on poly silicon to be the floating gate electrodes 4 and the poly silicon to be the second control-gate electrodes 8.

A poly silicon that is to be the first control-gate electrodes 6 and poly silicon that is to be the upper-layer gate electrodes 6′ are deposited both in the memory-cell-transistor region and in the peripheral-circuit-transistor region as shown in FIGS. 14A and 14B, respectively. Note that the laminated insulating film 5 is not necessary in the peripheral-circuit-transistor region shown in FIG. 14B. Accordingly, unillustrated resist is formed to cover the memory-cell-transistor region, then the poly silicon to be the upper-layer gate electrodes 6′ and some parts of the laminated insulating film 5 are removed by an etching process, and then the poly silicon to be the upper-layer gate electrodes 6′ is deposited. Accordingly, the first control-gate electrodes 6 are formed on the laminated insulating film 5, and the poly silicon to be the upper-layer gate electrodes 6′ is formed on the lower-layer gate electrodes 4′ and the laminated insulating film 5.

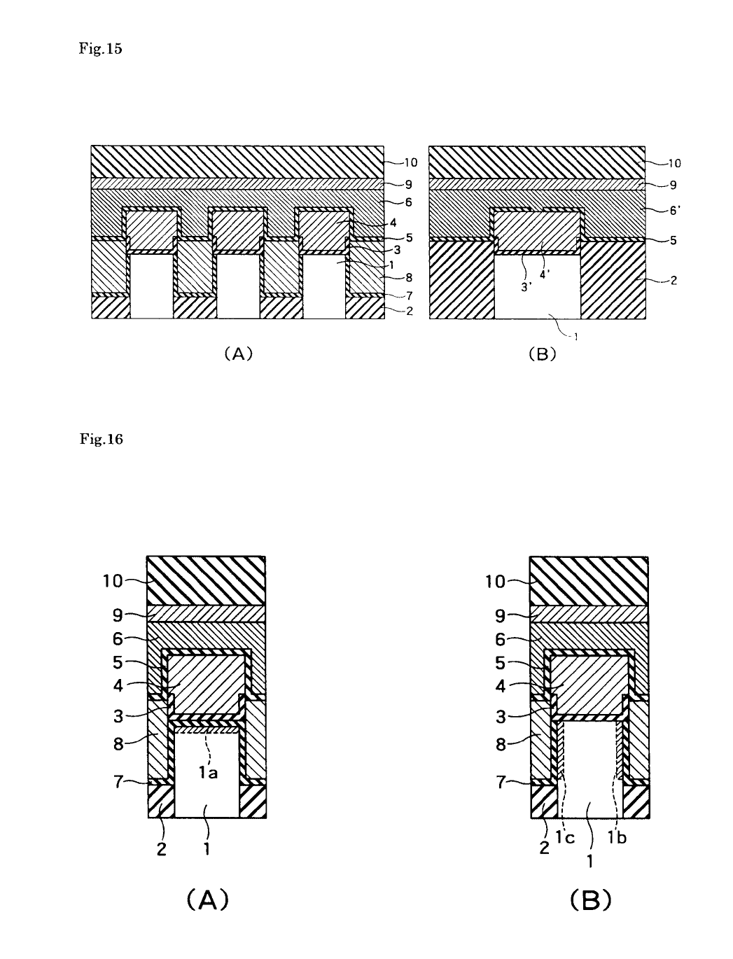

The metal layer 9 is deposited both on the poly silicon to be the first control-gate electrodes 6 in the memory-cell-transistor region and on the poly silicon to be the upper-layer gate electrodes 6′ in the peripheral-circuit-transistor region as shown in FIGS. 15A and 15B, respectively. Then, the TEOS film 10 is formed on the metal layer 9.

The non-volatile semiconductor memory device shown in FIG. 1 according to the embodiment of the present invention is thus manufactured through the series of processes shown in FIGS. 3 to 15.

Subsequently, description will be given of how the non-volatile semiconductor memory device according to the embodiment of the present invention operates. Both of FIGS. 16A and 16B are enlarged views each illustrating the region demarcated by the dashed line B of FIG. 1B.

In the reading operation of the non-volatile semiconductor memory device according to the embodiment of the present invention, the first control-gate electrodes 6 s operate as the electrodes to control the floating gate electrodes 4 in each of FIGS. 16A and 16B. In addition, the second control-gate electrodes 8 operate as the electrodes to control the nitride-film trap layers of the assist insulating films 7. FIG. 16A shows a channel region 1a formed below each floating gate electrode 4 of the element region (hereafter, the channel region 1a will be referred to as the “floating-gate channel region 1a). The floating-gate channel regions 1a are controlled by the first control-gate electrodes 6. FIG. 16B shows channel regions 1b and 1c formed in the sidewall gates (hereafter, the channel regions 1b and 1c will be referred to as the “sidewall-gate channel regions 1b and 1c”). The sidewall-gate channel regions 1b and 1c are controlled by the second control-gate electrodes 8. Accordingly, the floating gate electrodes 4 and the nitride-film trap layers of the assist insulating films 7 are controlled independently of each other. In addition, both in the writing operation and in the erasing operation, the floating gate electrodes 4 and the nitride-film trap layers of the assist insulating films 7 can be controlled independently of each other.

Subsequently, description will be given of the operational principle in a case where the non-volatile semiconductor memory device according to the embodiment of the present invention is a four-value non-volatile semiconductor memory device.

### Operational Example 1

### Case of Using Floating Gate Electrode and Assist Insulating Film as Single Memory Cell

In the writing operation into the floating gate electrode 4, electrons are injected into the floating gate electrode 4 by channel hot carriers with the potentials set as follows. For instance, both the source voltage and the substrate voltage are 0 V. The voltage to be applied to the first control-gate electrodes 6 (hereafter, this voltage is referred to as the “first-control-gate voltage”) and the drain voltage are any that are higher than both the source voltage and the substrate voltage (i.e., a positive voltage). Under such conditions, the voltage to be applied to the second control-gate electrodes 8 (hereafter, this voltage is referred to as the “second-control-gate voltage”) is set so that electrons can be trapped also in the nitride-film trap layers of the assist insulating films 7 by the channel hot carriers. To put it differently, a predetermined first writing voltage is applied to the first control-gate electrodes 6 whereas a second writing voltage is applied to the second control-gate electrodes 8. The applications of the voltage are done in a single sequence. If the gate voltage is changed from one value to another, the amount of electrons to be injected into the floating gate electrodes 4 and the amount of electrons to be introduced into the assist insulating films 7 can be adjusted. Thus, the non-volatile semiconductor memory device according to the embodiment of the present invention can operate as a four-value non-volatile semiconductor memory device. Note that the first writing voltage and the second writing voltage may have either the same value or different values from each other. For instance, suppose a case where data are written into a memory cell MF1 that includes the floating gate electrode 4 and is shown in FIG. 1B and into memory cells MS1 and MS2 that include assist insulating films 7 and are shown in FIG. 1B. A potential that is higher than both the source voltage and the substrate voltage (i.e., a positive potential) is applied to the bit-line contacts BC connected to the element region that are in contact with the above-mentioned memory cells MF1, MS1, and MS2. The bit-line contacts BC connected to the element regions that is not in contact with any of the above-mentioned memory cell MF1 and the memory cells MS1 and MS2 including the assist insulating films 7 are left in a floating state. Specifically, the element region that is in contact with the memory cell MS3 is left in a floating state. To write data into the memory cells MS1 and MS2, the second-control-gate voltage is applied both to the second control-gate electrode 8 that is in contact with the memory cell MS1 and to the second control-gate electrode 8 that is located between the memory cell MS2 and the memory cell MS3. Here, it seems that data would be written not only into the memory cells MS1 and MS2 but also into the memory cell MS3. The current (electrons), however, does not flow through the element region that is in contact with the memory cell MS3 because this element region is in a floating state. Accordingly, electrons are trapped in the assist insulating films 7 of the memory cells MS1 and MS2 by the channel hot carriers while no electron is trapped in the assist insulating film 7 of the memory cell MS3. Thus, the memory cells MF1, MS1, and MS2 can be combined together to serve as a single memory cell. In the erasing operation from the floating gate electrode 4, electrons are taken away from the floating gate electrode 4 by the Fowler-Nordheim (FN) tunnel effect while the potentials are set as follows. For instance, the first-control-gate voltage is set at 0 V. The source is in a floating state (open state). Both the drain voltage and the substrate voltage are set higher than 0 V and at the same potential (e.g., 20 V). Under such conditions, the second-control-gate voltage is set so that holes can be trapped in the nitride-film trap layers of the assist insulating films 7. In short, the first control-gate electrode and the second-control-gate electrode are set at the same potential. The applications of the voltage are done in a single sequence.

In the reading operation from the floating gate electrodes 4, the readout voltage is set so that the second-control-voltage can be equal to the first-control-gate voltage while other potentials are set as follows. For instance, the drain voltage is set at 3 V while both the source voltage and the substrate voltage are set at 0 V. The readout voltage changes arbitrarily depending upon the data to be read out. Accordingly, an identical readout voltage is applied both to the first control-gate electrodes 6 and to the second control-gate electrodes 8. Suppose a case where a readout voltage that turns a memory-cell transistor to the ON state is applied both to the first control-gate electrodes 6 and to the second control-gate electrodes 8. In this case, in addition to the ordinary channel region, the sidewall-gate channel regions 1b and 1c shown in FIG. 16B are formed in the nitride-film trap layers of the assist insulating films 7. To put it differently, the current flows through not only the ordinary channel region but also the sidewall-gate channel region 1b and 1c so as to make the transconductance higher. Consequently, the readout current in the reading operation becomes extremely large. To put it differently, according to Operational Example 1, a wider margin for the data-reading operation can be achieved.

### Operational Example 2

### Case of Using Floating Gate Electrode and Assist Insulating Film as Different Memory Cells

In the writing operation into the floating gate electrode 4, electrons are introduced into the floating gate electrode 4 by channel hot carriers with the potentials set as follows. For instance, both the source voltage and the substrate voltage are 0 V. A positive potential is applied as the first-control-gate voltage and the drain voltage. Under such conditions, the second-control-gate voltage is set so that the electrons can be prevented from being trapped, by the channel hot carriers, in the nitride-film trap layers of the assist insulating films 7. For instance, the second control-gate electrode 8 is left in a floating state.

Next, description will be given of a case of the writing operation in the nitride-film trap layers of the assist insulating films 7 that are in contact with the sidewall-gate channel regions 1b and 1c formed respectively on the two sides of each second control-gate electrode 8 in FIG. 16B. In this case, both the source voltage and the substrate voltage are set at 0 V whereas both the second-control-gate voltage and the drain voltage are set at positive potentials, for example. Under the conditions, electrons are trapped in the nitride-film trap layers of the assist insulating films 7 by the channel hot carriers. Here, the first-control-gate voltage is set so that no electrons are introduced into the floating gate electrode 4. For instance, the first control-gate electrode 6 is left in the floating state.

For instance, suppose a case where data are written into the memory cells MS1 and MS2 shown in FIG. 1B and including assist insulating films 7. A potential that is higher than both the source voltage and the substrate voltage (i.e., a positive potential) is applied to the bit-line contacts BC connected to the element region that are in contact with the above-mentioned memory cells MF1, MS1, and MS2. The bit-line contacts BC connected to the element region that are not in contact with any of the above-mentioned memory cells MF1 and the memory cells MS1 and MS2 including the assist insulating films 7 are left in a floating state. Specifically, the element region that is in contact with the memory cell MS3 is left in a floating state. To write data into the memory cells MS1 and MS2, the second-control-gate voltage is applied both to the second control-gate electrode 8 that is in contact with the memory cell MS1 and to the second control-gate electrode 8 that is located between the memory cell MS2 and the memory cell MS3. Here, it seems that data would be written not only into the memory cell MS2 but also into the memory cell MS3. The current (electrons), however, does not flow through the element region that is in contact with the memory cell MS3 because this element region is in a floating state. Accordingly, electrons are trapped in the assist insulating films 7 of the memory cells MS1 and MS2 by the channel hot carriers while no electron is trapped in the assist insulating film 7 of the memory cell MS3. Thus, the memory cells MS1 and MS2 can be combined together to serve as a single memory cell.

In the erasing operation from the floating gate electrode 4, electrons are taken away from the floating gate electrode 4 by the Fowler-Nordheim (FN) tunnel effect while the potentials are set as follows. For instance, the first-control-gate voltage is set at 0 V. The source is in a floating state (open state). The drain voltage and the substrate voltage are set at the same potential (e.g., 20 V). Here, the second-control-gate voltage is set so that holes can be prevented from being introduced into the nitride-film trap layers of the assist insulating films 7. For instance, the second control-gate electrode 8 is left in a floating state.

Next, description will be given of a case of the erasing operation from the nitride-film trap layer of the assist insulating film 7 that is in contact with the sidewall-gate channel regions 1b and 1c formed respectively on the two sides of each second control-gate electrode 8 in FIG. 16B and. In this case, the sidewall-gate voltage is set at 0 V, the source is in a floating state (open state), and both the drain voltage and the substrate voltage are set at 20 V, for instance. Under the conditions, holes are injected into the nitride trap film of the assist insulating film 7 by the channel hot carriers. The floating-gate voltage is set so that the electrons are prevented from being taken away from the floating gate electrode 4. For instance, the floating gate electrode 4 is left in a floating state.

In the reading operation from the floating gate electrodes 4, the first-control-gate voltage is set at a readout voltage while other potentials are set as follows. For instance, the drain voltage is set at 3 V while both the source voltage and the substrate voltage are set at 0 V. The readout voltage changes arbitrarily depending upon the data to be read out. Here, the second-control-gate voltage is set so that data can not be read out from the nitride trap film of the assist insulating film 7. For instance, the second control-gate electrode 8 is left in a floating state.

In the reading operation from the assist insulating film 7, the second-control-gate voltage is set at a readout voltage while other potentials are set as follows. For instance, the drain voltage is set at 3 V while both the source voltage and the substrate voltage are set at 0 V. The readout voltage changes arbitrarily depending upon the data to be read out. Here, the first-control-gate voltage is set so that data can not be read out from floating gate electrode 4. For instance, the first control-gate electrode 6 is left in a floating state.

According to the operational method, the floating gate electrode 4 and the assist insulating film 7 can be used as independent memory cells. For instance, even when two-value data are stored in each of the floating gate electrode 4 and the assist insulating film 7, the memory cells formed by the floating gate electrode 4 and the assist insulating film 7 can store four-value data.

### Operational Example 3

### Case of Storing Eight-Value Data in Single Memory Cell by Storing Four-Value Data in Each of Floating Gate Electrode and Assist Insulating Film

To this end, in the non-volatile semiconductor memory device of Operational Example 2, each of the floating gate electrode 4 and the assist insulating film 7 is made to store four-value data.

### Operational Example 4

### Case of Storing Eight-Value Data in Single Memory Cell by Combining Floating Gate Electrode and Assist Insulating Film Together to be Used as Single Memory Cell

To this end, in the non-volatile semiconductor memory device of Operational Example 1, the floating gate electrode 4 and the assist insulating film 7 combined together are made to store eight-value data.

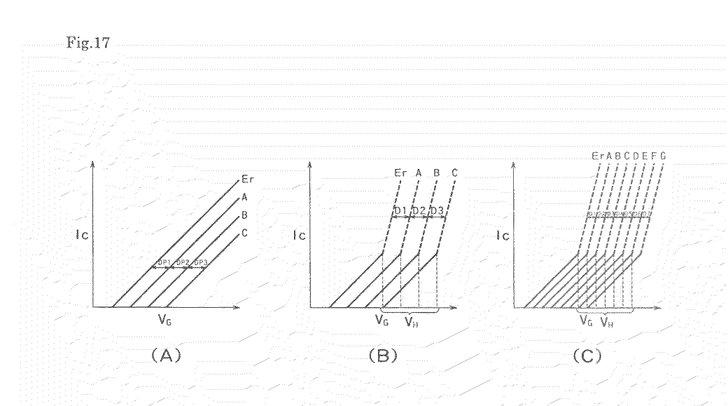

Subsequently, description will be given of a comparative example of Operational Example 1 of the embodiment of the present invention. FIG. 17 shows graphs to describe the comparative example of the embodiment of the present invention. FIG. 17A is a graph illustrating the readout characteristics of a conventional non-volatile semiconductor memory device (of four values). FIG. 17B is a graph illustrating the readout characteristics of the non-volatile semiconductor memory device (of four values) according to Operational Example 1 of the embodiment of the present invention. FIG. 17C is a graph illustrating the readout characteristics of the non-volatile semiconductor memory device (of eight values) according to Operational Example 4 of the embodiment of the present invention. In each of FIGS. 17A to 17C, the horizontal axis represents the gate voltage (VG) whereas the vertical axis represents the cell current (IC). Note that the same gate voltage (VG) is applied both to the first control-gate electrode 6 and to the second control-gate electrode 8. To put it differently, both the first-control-gate voltage and the second-control-voltage have the same value.

As FIG. 17A shows, the conventional non-volatile semiconductor memory device (of four values) exhibits linear characteristics for each of the values (“Er,” “A,” “B,” and “C”). A distance DP1 is the difference between the value “Er” and the value “A.” A distance DP2 is the difference between the value “A” and the value “B.” A distance DP3 is the difference between the value “B” and the value “C.”

In contrast, as FIG. 17B shows, the non-volatile semiconductor memory device (of four values) according to Operational Example 1 of the embodiment of the present invention exhibits the following characteristics. Each of the values (“Er,” “A,” “B,” and “C”) has a slope that is similar to the one exhibited in the case of the conventional non-volatile semiconductor memory device shown in FIG. 17A until the gate voltage (VG) reaches a predetermined gate voltage (hereafter, the predetermined gate voltage will be referred to as the “inflection voltage VH”). Once the gate voltage (VG) exceeds the inflection voltage VH, each of the values (“Er,” “B,” and “C”) has a slope that is different from the one exhibited in the case of the conventional non-volatile semiconductor memory device shown in FIG. 17A. The above-mentioned inflection voltage VH refers to a voltage that, if applied to the second control-gate electrode 8, can form channels in the sidewall-gate channel regions. In the conventional non-volatile semiconductor memory device, a channel is formed in the floating-gate channel region 1a shown in FIG. 16A. Also in the non-volatile semiconductor memory device (of four values) according to Operational Example 1, a channel is formed in the floating-gate channel region 1a shown in FIG. 16A as in the conventional case. In addition, in the non-volatile semiconductor memory device (of four values) according to Operational Example 1, channels are formed in the sidewall-gate channel regions 1b and 1c shown in FIG. 16B, resulting in an increase in the cell current (IC).

As FIGS. 17A and 17B show, once the gate voltage (VG) exceeds the inflection voltage VH, the cell current (IC) is supplemented with an additional current. The distances D1 to D3 each between every two of the values (“Er,” “A,” “B,” and “C”) represent the margin for the reading operation. Once the gate voltage (VG) exceeds the inflection voltage VH, the distances D1 to D3 become wider than the distances DP1 to DP3 between the values exhibited in the case of the conventional non-volatile semiconductor memory device shown in FIG. 17A. Accordingly, the transconductance becomes higher, and the readout current at the time of the data-reading operation becomes extremely large.

The non-volatile semiconductor memory device (of eight values) according to Operational Example 4 of the embodiment of the present invention and shown in FIG. 17C exhibits a similar tendency to the one exhibited by the non-volatile semiconductor memory device (of four values) according to Operational Example 1 of the embodiment of the present invention and shown in FIG. 17B. As FIG. 17C shows, the non-volatile semiconductor memory device (of eight values) according to Operational Example 4 of the embodiment of the present invention exhibits the following characteristics. Each of the values (“Er,” “A,” “B,” “C,” “D,” “E,” “F,” and “G”) has a slope that is similar to the one exhibited in the case of the conventional non-volatile semiconductor memory device shown in FIG. 17A until the gate voltage (VG) reaches the inflection voltage VH. Once the gate voltage (VG) exceeds the inflection voltage VH, each of the values “Er,” “A,” “B,” “C,” “D,” “E,” “F,” and “G”) has a slope that is different from the one exhibited in the case of the conventional non-volatile semiconductor memory device shown in FIG. 17A. Accordingly, once the gate voltage (VG) exceeds the inflection voltage VH, the distances D1 to D7 between the values (the margin for the data-reading operation) become wider than the distances DP1 to DP3 between the values exhibited in the case of the conventional non-volatile semiconductor memory device shown in FIG. 17A. Accordingly, the transconductance becomes higher, and the readout current in the reading operation becomes extremely large. Note that the upper-limit value “G” in the case of the eight-value non-volatile semiconductor memory device cannot be much higher than the upper-limit value “C” in the case of the four-value non-volatile semiconductor memory device. Accordingly, to store data of eight values in the eight-value non-volatile semiconductor memory device, each of the distances D1 to D7 between the values is shortened. To put it differently, as the number of values to be stored in a single memory cell becomes larger, the effect of the embodiment of the present invention becomes larger.

According to the embodiment of the present invention, the sidewall-gate channel regions 1b and 1c are formed in the nitride-film trap layers of the assist insulating films 7, so that the current is supplemented by an additional current. Accordingly, the transconductance becomes lower and the readout current at the time of the data-reading operation becomes extremely small. Put it differently, the margin for the data-reading operation can be made larger. Consequently, errors in data reading are less likely.

In addition, according to the embodiment of the present invention, the voltage applied to the first control-gate electrode 6 is different from the voltage applied to the second control-gate electrode 8 (that is, the floating gate electrode 4 is controlled independently of the sidewall gate electrodes), the multi-value level of the memory-cell transistor can be variable. Consequently, the non-volatile semiconductor memory device can have broader utility.

In addition, according to the embodiment of the present invention, the second control-gate electrodes 8 are formed so that the top surfaces of the second control-gate electrodes 8 can be positioned at a higher level than the top surfaces of the sidewall-gate channel regions 1b and 1c. The distance between each of the sidewall-gate channel regions 1b and 1c and the laminated insulating film 5 becomes wider. Accordingly, the breakage of the laminated insulating film 5 (the so-called inter-poly dielectric=IPD breakage) can be prevented. Consequently, the non-volatile semiconductor memory device can be made more reliable.

In addition, according to the embodiment of the present invention, the second control-gate electrodes 8 formed in the sidewalls of the substrate's active areas can serve as shield against the inter-cell interference. Accordingly, the fluctuation of threshold for the adjacent memory-cell transistors can be decreased.

The embodiment described thus far should be understood not as something that limits the present invention but as a mere example of the present invention. The technical scope of the present invention is indicated by the claims, and includes every feature equivalent to the ones described in the claims and every modification made within the technical scope of the present invention.

What is claimed is:

1. A non-volatile semiconductor memory device comprising:
a semiconductor substrate;
an element isolation insulating film dividing the semiconductor substrate into a plurality of element regions;
tunnel insulating films formed respectively on the plurality of element regions;
floating gate electrodes formed respectively on the tunnel insulating films;
a first control-gate electrode formed, on the floating gate electrodes and between each two floating gate electrodes adjacent to each other in a channel-width direction, with a laminated insulating film interposed therebetween;
assist insulating films formed on side surface facing in the channel-width direction of the plurality of element regions; and
a second control-gate electrode formed between the plurality of element regions with the assist insulating films interposed therebetween.

2. The non-volatile semiconductor memory device according to claim 1 wherein, in a reading operation, an identical readout voltage is applied to both of the first control-gate electrode and the second control-gate electrode.

3. The non-volatile semiconductor memory device according to claim 1 wherein, in a writing operation, a first writing voltage is applied to the first control-gate electrode and a second writing voltage that differs from the first writing voltage is applied to the second control-gate electrode.

4. The non-volatile semiconductor memory device according to claim 1, wherein a top surface of the second control-gate electrode is positioned at a higher level than top surfaces of the plurality of element regions.

5. A non-volatile semiconductor memory device comprising:
a semiconductor substrate;
first element-isolation insulating films extending in a channel-length direction and dividing the semiconductor substrate into a plurality of first element regions;
tunnel insulating films formed respectively on the plurality of first element regions;
charge-accumulating layers formed respectively on the tunnel insulating films;
a first insulating film formed on the charge-accumulating layer;
a first gate electrode formed on the first insulating film and extending in a channel-width direction that intersects the channel-length direction;
assist insulating films formed on side surface facing in the channel-width direction of the plurality of first element regions; and
second gate electrodes formed between the plurality of first element regions with the assist insulating films interposed therebetween.

6. The non-volatile semiconductor memory device according to claim 5, wherein
each of the assist insulating films has a U-shape,
each of a bottom surface of the U-shaped assist insulating films is contacting with a top surface of the corresponding one of the first element-isolation insulating films, and
each of both side surfaces of the U-shaped assist insulating films are contacting with a side surface respectively of the first element regions that sandwich the U-shaped assist insulating film.

7. The non-volatile semiconductor memory device according to claim 5, wherein each of a top surface of the second gate electrodes is contacting with a bottom surface of the first insulating film.

8. The non-volatile semiconductor memory device according to claim 5, wherein
each of the tunnel insulating films has a U-shape, and
each of both side surfaces of the U-shaped tunnel insulating films are contacting with upper portions of the corresponding ones of the second gate electrodes.

9. The non-volatile semiconductor memory device according to claim 5, further comprising:
second element-isolation insulating films situated in a peripheral-circuit region and dividing the semiconductor substrate into second element regions; and
third gate electrodes formed on the second element regions with gate insulating films interposed therebetween, wherein
all the side surface of the second element regions are contacting with the second element-isolation insulating films.

10. The non-volatile semiconductor memory device according to claim 9, wherein
each of the gate insulating films has a U-shape, and
each of both side surfaces of the U-shaped gate insulating films are contacting with upper portions of the corresponding ones of the second element-isolation insulating films.

11. A method of manufacturing a non-volatile semiconductor memory device comprising the steps of:
forming a stopper insulating film on a semiconductor substrate;
etching the semiconductor substrate and the stopper insulation film, and thereby forming element-isolation grooves to divide the semiconductor substrate into a plurality of element regions;
forming element-isolation insulating films by burying insulating films into the element-isolation grooves;
etching back the element-isolation insulating films to a predetermined depth so that a side surface of the plurality of element regions are exposed;
forming assist insulating films on the side surface of the plurality of element regions exposed from the element-isolation insulating films, on the stopper insulating film, and on the element-isolation insulating films;
forming second control-gate electrodes between the plurality of element regions with the assist insulating films interposed therebetween;
forming tunnel insulating films on the plurality of element regions respectively;
forming floating gate electrodes on the tunnel insulating films respectively;
forming a laminated insulating film on the floating gate electrodes and on the second control-gate electrodes; and
forming a first control-gate electrode on the laminated insulating film.

12. The method of manufacturing a non-volatile semiconductor memory device according to claim 11, wherein the step of forming the tunnel insulating film on the plurality of element regions respectively includes:
removing the stopper insulating film so as to expose the top surfaces of the plurality of element regions; and
forming the tunnel insulating films on the exposed top surfaces of the plurality of element regions respectively.

13. The method of manufacturing a non-volatile semiconductor memory device according to claim 11, wherein the step of forming the floating gate electrodes includes:
forming mask members respectively on the second control-gate electrodes;
forming a conductive material between the mask members; and
removing the mask members.

14. The method of manufacturing a non-volatile semiconductor memory device according to claim 11, wherein the step of forming the tunnel insulating film on the plurality of element regions respectively and the step of forming the floating gate electrodes include:
forming mask members respectively on the second control-gate electrodes;
removing the stopper insulating film so as to expose top surfaces of the plurality of element regions;
forming the tunnel insulating film on the exposed top surfaces of the plurality of element regions;
forming a conductive material between the mask members and on the tunnel insulating film; and
removing the mask members and thereby forming the floating gate electrode.

15. The method of manufacturing a non-volatile semiconductor memory device according to claim 11, wherein the step of forming the assist insulating films includes forming the assist insulating films into a U-shape along the exposed sidewalls of the plurality of element regions and along the element-isolation insulating films.

16. The method of manufacturing a non-volatile semiconductor memory device according to claim 15, wherein the step of forming the second control-gate electrodes includes:
burying a conductive material into the U-shaped assist insulating films; and
leaving the conductive material between the assist insulating films by using the stopper insulating film as a stopper.

17. The method of manufacturing a non-volatile semiconductor memory device according to claim 11, wherein the step of etching back the element-isolation insulating films to the predetermined depth includes lowering top surfaces of the element-isolation insulating films to a level that is lower than a bottom surface of the stopper insulating film.
